(19) United States
(12) Patent Application Publication
(10) Pub. No.: US 2010/0008043 A1
(43) Pub. Date: Jan. 14, 2010

(54) HEAT-TRANSPORTING DEVICE, ELECTRONIC APPARATUS, SEALING APPARATUS, SEALING METHOD, AND METHOD OF PRODUCING A HEAT-TRANSPORTING DEVICE

(75) Inventors: Takashi Yajima, Tokyo (JP); Hiroyuki Ryoson, Kanagawa (JP); Kazuo Goto, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/496,944

(22) Filed: Jul. 2, 2009

(30) Foreign Application Priority Data
Jul. 10, 2008 (JP) 2008-180763

(51) Int. Cl. H05K 7/20; F28D 15/02; F28D 15/00; B23K 26/00; F16J 15/02

(52) U.S. Cl. 361/700; 165/104.26; 165/104.21; 219/121.64; 277/650; 277/312

(57) ABSTRACT

A heat-transporting device includes a casing, a working fluid, a first substrate, a second substrate, and a third substrate. The casing includes a first side and a second side opposed to the first side. The working fluid is sealed inside the casing and transports heat by a phase change. The first substrate includes an inlet through which the working fluid is injected and constitutes the first side of the casing. The second substrate is disposed opposite to the first substrate and constitutes the second side of the casing. The third substrate includes a contact portion that is brought into contact with the inlet so that the inlet is sealed when the inlet is pressed, the third substrate being interposed between the first substrate and the second substrate.

### BACKGROUND OF THE INVENTION

1. Field of the Invention

The present invention relates to a heat-transporting device for cooling a heat source using a phase change of a working fluid, an electronic apparatus including the heat-transporting device, a sealing apparatus for sealing the working fluid inside the heat-transporting device, a sealing method for sealing the working fluid, and a method of producing a heat-transporting device.

2. Description of the Related Art

From the past, a planar heat pipe is widely used as a device for cooling a heat source such as a CPU (Central Processing Unit) of a PC (Personal Computer) (see, for example, Japanese Patent Application Laid-open No. 2004-238672 (paragraphs [0020] to [0021], FIGS. 1 to 3) and Japanese Patent Application Laid-open No. 2007-315745 (paragraphs [0159] to [0178], FIGS. 19 to 23); hereinafter, referred to as Patent Documents 1 and 2, respectively). In the planar heat pipe as described above, the CPU or the like is cooled using a change in a gas phase of a working fluid. Therefore, the working fluid is sealed in the planar heat pipe.

For example, Patent Document 1 discloses a planar heat pipe in which a through-hole penetrating to an inside is formed on a side wall portion and a nozzle is attached to the through-hole. In this planar heat pipe, a noncondensable gas such as air is discharged via the nozzle and a condensable working fluid such as water is injected via the nozzle. After that, the nozzle is closed so that the working fluid is sealed in the heat pipe.

Moreover, Patent Document 2 discloses a planar heat pipe in which a cooling-medium injecting hole and an air discharging hole are formed on an outer surface. In the planar heat pipe disclosed in Patent Document 2, after a cooling medium such as water is injected via the cooling-medium injecting hole, a spherical thermoplastic metal such as solder is placed on the cooling-medium injecting hole and the air discharging hole. Then, after the spherical thermoplastic metal is pressure-deformed in a low-temperature state and the cooling-medium injecting hole and the air discharging hole are thus sealed temporarily, the thermoplastic metal is pressure-deformed in a high-temperature state to thus seal the cooling-medium injecting hole and the air discharging hole.

### SUMMARY OF THE INVENTION

However, because the planar heat pipe disclosed in Patent Document 1 has a structure in which the nozzle is attached to the through-hole, the structure of the heat pipe becomes complex and a task of attaching the nozzle may become necessary, thus leading to an increase in costs. Moreover, although it is desirable to keep the heat pipe airtight, a bonded portion between the through-hole and the nozzle lowers reliability on airtightness. In addition, there is a problem that, when the nozzle is closed, the closed nozzle portion remains as a protrusion.

On the other hand, in the heat pipe disclosed in Patent Document 2, because the cooling-medium injecting hole and the air discharging hole are sealed by a plastic flow of the thermoplastic metal such as solder, the problem on the protrusion can be relieved.

However, because the thermoplastic metal is used as a hole sealing member, there is a problem that reliability on internal airtightness of the heat pipe is low. For example, there is a case where, after the heat pipe is completed, heat is applied to the heat pipe in a reflow process at a time of attaching the heat pipe to another component. At that time, due to a meltdown or softening of the thermoplastic metal as the sealing member, a gap may be caused between the holes, thus resulting in a problem that internal airtightness of the heat pipe is difficult to be maintained.

In view of the circumstances as described above, there is a need for a heat-transporting device that does not cause a protrusion when sealing an inlet through which a working fluid is injected and is capable of improving reliability on internal airtightness, a sealing apparatus for sealing the working fluid in the heat-transporting device, and other techniques.

According to an embodiment of the present invention, there is provided a heat-transporting device including a casing, a working fluid, a first substrate, a second substrate, and a third substrate.

The casing includes a first side and a second side opposed to the first side.

The working fluid is sealed inside the casing and transports heat by a phase change.

The first substrate includes an inlet through which the working fluid is injected and constitutes the first side of the casing.

The second substrate is disposed opposite to the first substrate and constitutes the second side of the casing.

The third substrate includes a contact portion that is brought into contact with the inlet so that the inlet is sealed when the inlet is pressed, the third substrate being interposed between the first substrate and the second substrate.

In the embodiment of the present invention, because the inlet is sealed when the inlet is pressed and brought into contact with the contact portion, a protrusion is not caused. Moreover, because a thermoplastic metal such as solder is not used as a sealing member in sealing the inlet, reliability on internal airtightness of the heat-transporting device can be improved. Furthermore, because the heat-transporting device is constituted of substrates, a reduction in size and thickness of the heat-transporting device becomes possible.

The heat-transporting device may further include a fourth substrate.

The fourth substrate includes an opening that forms a space for pressing the inlet, the fourth substrate being interposed between the first substrate and the third substrate.

According to the embodiment of the present invention, a space for pressing the inlet can be formed by the third substrate.

In the heat-transporting device, the second substrate may include a groove that constitutes a gas-phase flow path through which the working fluid of a gas phase flows.

According to the embodiment of the present invention, due to the provision of the groove that constitutes the gas-phase flow path, the working fluid of the gas phase can be caused to flow therethrough.

In the heat-transporting device, the third substrate may have a frame structure, and the heat-transporting device may further include a plurality of liquid-phase flow path substrates.

The plurality of liquid-phase flow path substrates each include a plurality of holes and are laminated inside the frame such that a liquid-phase flow path constituted of the plurality of holes is in communication with the space.

The plurality of holes constitute the liquid-phase flow path through which the working fluid of a liquid phase flows by a capillary force.

According to the embodiment of the present invention, it is possible to cause the working fluid of the liquid phase to flow by the capillary force of the plurality of holes. Moreover, because the liquid-phase flow path constituted of the plurality of holes is in communication with the space, the working fluid that has been injected from the inlet and has entered the space can be led inside the casing smoothly.

The “plurality of holes” may be formed by simply forming holes on the substrates or may be a plurality of holes in a mesh structure.

In the heat-transporting device, the third substrate may further include a plurality of holes.

The plurality of holes constitute a liquid-phase flow path through which the working fluid of a liquid phase flows by a capillary force, the plurality of holes being formed such that the liquid-phase flow path constituted of the plurality of holes is in communication with the space.

Accordingly, since the liquid-phase flow path constituted of the plurality of holes is in communication with the space, the working fluid that has been injected from the inlet and has entered the space can be led inside the casing smoothly.

In the heat-transporting device, the fourth substrate may further include a plurality of holes.

The plurality of holes constitute a liquid-phase flow path through which the working fluid of a liquid phase flows by a capillary force, the plurality of holes being formed such that the liquid-phase flow path constituted of the plurality of holes is in communication with the space.

Accordingly, since the liquid-phase flow path constituted of the plurality of holes is in communication with the space, the working fluid of the liquid phase that has been injected from the inlet and has entered the space can be led inside the casing smoothly.

In the heat-transporting device, the second substrate may further include a supporting portion provided inside the groove to support the contact portion when the inlet is pressed.

According to the embodiment of the present invention, because the supporting portion supports the contact portion, the inlet can be sealed positively.

In the heat-transporting device, the second substrate may further include a column provided inside the groove along a directing in which the working fluid of the gas phase flows.

For example, there is a case where a pressure inside the casing rises due to heat from a heat source and the heat-transporting device is thus deformed. According to the embodiment of the present invention, due to the column provided inside the groove, the deformation of the heat-transporting device can be suppressed even when the pressure inside the casing rises due to the heat from the heat source.

The heat-transporting device may further include a plurality of liquid-phase flow path substrates.

The plurality of liquid-phase flow path substrates each include a plurality of holes that constitute a liquid-phase flow path through which the working fluid of a liquid phase flows by a capillary force, the plurality of liquid-phase flow path substrates being laminated while interposed between the second substrate and the third substrate.

According to another embodiment of the present invention, there is provided a heat-transporting device including a casing, a working fluid, and a contact portion.

The casing includes an inlet.

The working fluid is injected into the casing via the inlet and transports heat by a phase change.

The contact portion is provided inside the casing and brought into contact with the inlet to seal the inlet when the inlet is pressed.

In the embodiment of the present invention, because the inlet is sealed when the inlet is pressed and brought into contact with the contact portion, a protrusion is not caused. Moreover, because a thermoplastic metal such as solder is not used as the sealing member in sealing the inlet, reliability on internal airtightness of the heat-transporting device can be improved.

According to an embodiment of the present invention, there is provided an electronic apparatus including a heat source and a heat-transporting device.

The heat-transporting device includes a casing, a working fluid, and a contact portion.

The casing includes an inlet.

The working fluid is injected into the casing via the inlet and transports heat by a phase change.

The contact portion is provided inside the casing and brought into contact with the inlet to seal the inlet when the inlet is pressed.

According to an embodiment of the present invention, there is provided a sealing apparatus sealing a working fluid in a heat-transporting device that includes a casing including an inlet through which the working fluid for transporting heat by a phase change is injected, the casing sealing the working fluid therein, and a contact portion that is provided inside the casing and brought into contact with the inlet to seal the inlet when the inlet is pressed, the sealing apparatus including a discharging member and a first driving member.

The discharging member includes a tip end portion and an outlet provided at the tip end portion from which the working fluid is discharged, the discharging member discharging the working fluid into the casing from the outlet via the inlet.

The first driving member drives the discharging member so that the inlet is pressed by the tip end portion.

In the embodiment of the present invention, the working fluid can be injected from the outlet provided at the tip end portion of the discharging member via the inlet of the heat-transporting device. Moreover, after finishing injecting the working fluid into the heat-transporting device, the inlet can be sealed by driving the first driving member to thus press the inlet with the tip end portion of the discharging member. In other words, the sealing apparatus according to the embodiment of the present invention includes a function of injecting a working fluid and a function of sealing an inlet. Therefore, the working fluid can efficiently be sealed in the heat-transporting device.

In the sealing apparatus, the discharging member may be capable of exhausting the inside of the casing from the outlet via the inlet.

In the embodiment of the present invention, in addition to the function of injecting a working fluid and the function of sealing an inlet, a function of exhausting the inside of the heat-transporting device is provided. Accordingly, the working fluid can more efficiently be sealed in the heat-transporting device.

The sealing apparatus may further include an airtight mechanism to maintain a space formed between the discharging member and the inlet airtight.

Accordingly, the working fluid can be sealed in the heat-transporting device appropriately without being influenced by an external pressure.

In the sealing apparatus, the airtight mechanism may include an expanding/contracting member, a base, and a sealing member.

The expanding/contracting member is disposed around the discharging member and expands/contracts in accordance with the drive of the discharging member.

The base is bonded to the expanding/contracting member and includes a through-hole through which the driven discharging member is capable of moving.

The sealing member is provided to the base and seals the space by being brought into contact with the casing.

According to the embodiment of the present invention, airtightness of the spaced formed between the discharging member and the inlet can be maintained by the expanding/contracting member, the base, and the sealing member.

The sealing apparatus may further include a second driving member.

The second driving member drives the base and the sealing member so that the base and the sealing member are biased toward the casing.

In the embodiment of the present invention, because the base and the sealing member are biased toward the heat-transporting device by the second driving member, even when the discharging member moves when sealing the inlet, the base and the sealing member do not move. Accordingly, airtightness of the space formed between the discharging member and the inlet can be maintained appropriately.

According to an embodiment of the present invention, there is provided a working fluid sealing method including injecting a working fluid into a casing via an inlet provided to the casing.

The inlet is pressed and brought into contact with a contact portion provided inside the casing so as to be sealed.

Accordingly, the working fluid can easily be sealed in the heat-transporting device.

The working fluid sealing method may further include exhausting the inside of the casing via the inlet before the injection of the working fluid.

The working fluid sealing method may further include welding the inlet and the contact portion by irradiating laser onto the inlet after the sealing of the inlet.

Accordingly, the inlet can be sealed positively.

The working fluid sealing method may further include pressing, after the injection of the working fluid but before the welding of the inlet and the contact portion by the laser, a periphery of the inlet at a position apart from the inlet by a predetermined gap.

Accordingly, the inlet can be sealed positively.

According to an embodiment of the present invention, there is provided a method of producing a heat-transporting device including injecting a working fluid into a casing via an inlet provided to the casing.

The inlet is pressed and brought into contact with a contact portion provided inside the casing so as to be sealed.

Accordingly, a heat-transporting device that does not cause a protrusion and is capable of improving reliability on airtightness can easily be produced.

The method of producing a heat-transporting device may further include exhausting the inside of the casing via the inlet before the injection of the working fluid.

The method of producing a heat-transporting device may further include welding the inlet and the contact portion by irradiating laser onto the inlet after the sealing of the inlet.

Accordingly, a heat-transporting device having a positively-sealed inlet can be produced.

The method of producing a heat-transporting device may further include pressing, after the injection of the working fluid but before the welding of the inlet and the contact portion by the laser, a periphery of the inlet at a position apart from the inlet by a predetermined gap.

Accordingly, a heat-transporting device having a positively-sealed inlet can be produced.

As described above, according to the embodiments of the present invention, it is possible to provide a heat-transporting device that does not cause a protrusion when sealing an inlet through which a working fluid is injected and is capable of improving reliability on internal airtightness, a sealing apparatus for sealing the working fluid in the heat-transporting device, and other techniques.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is an exploded perspective view of a heat-transporting device according to an embodiment of the present invention;

FIG. 2 is a cross-sectional diagram of the heat-transporting device according to the embodiment of the present invention;

FIG. 3 is a top view of the heat-transporting device according to the embodiment of the present invention;

FIG. 4 is an enlarged diagram showing the vicinity of an end portion of a lower substrate;

FIG. 5 is an exploded perspective view showing a heat-transporting device according to another embodiment of the present invention;

FIG. 6 is an exploded perspective view of a heat-transporting device according to still another embodiment of the present invention;

FIG. 7 is a top view of the heat-transporting device according to still another embodiment of the present invention;

FIG. 8 are diagrams showing examples of a case where an opening has a shape other than a rectangle;

FIG. 9 is a perspective view of a lower substrate that includes columns inside a groove;

FIG. 10 is an overall view of a sealing apparatus for injecting a working fluid into the heat-transporting device;

FIG. 11 is a diagram showing a discharging mechanism of the sealing apparatus;

FIG. 12 is a diagram showing the discharging mechanism in a case where an O-ring is used instead of a bellows;

FIG. 13 is a flowchart showing a sealing method and a producing method according to an embodiment of the present invention;

FIG. 14 is a diagram showing a state where a discharging member is driven downwardly;

FIG. 15 is a diagram showing a state where a pressed inlet is irradiated with laser;

FIG. 16 is a flowchart showing a sealing method and a producing method according to another embodiment of the present invention;

FIG. 17 are diagrams respectively showing a state where the inlet is sealed and a state where two points on the periphery of the inlet are pressed;

FIG. 18 is a flowchart showing a sealing method and a producing method according to still another embodiment of the present invention;

FIG. 19 are cross-sectional diagrams of the heat-transporting device shown in FIGS. 6 and 7 taken along the line A-A′;

FIG. 20 is a diagram schematically showing a movement of heat in the heat-transporting device;

FIG. 21 are diagrams schematically showing the movement of heat in the heat-transporting device; and

FIG. 22 is a perspective view of a laptop PC.

### DESCRIPTION OF PREFERRED EMBODIMENTS

Hereinafter, embodiments of the present invention will be described with reference to the drawings.

### First Embodiment of Heat-Transporting Device

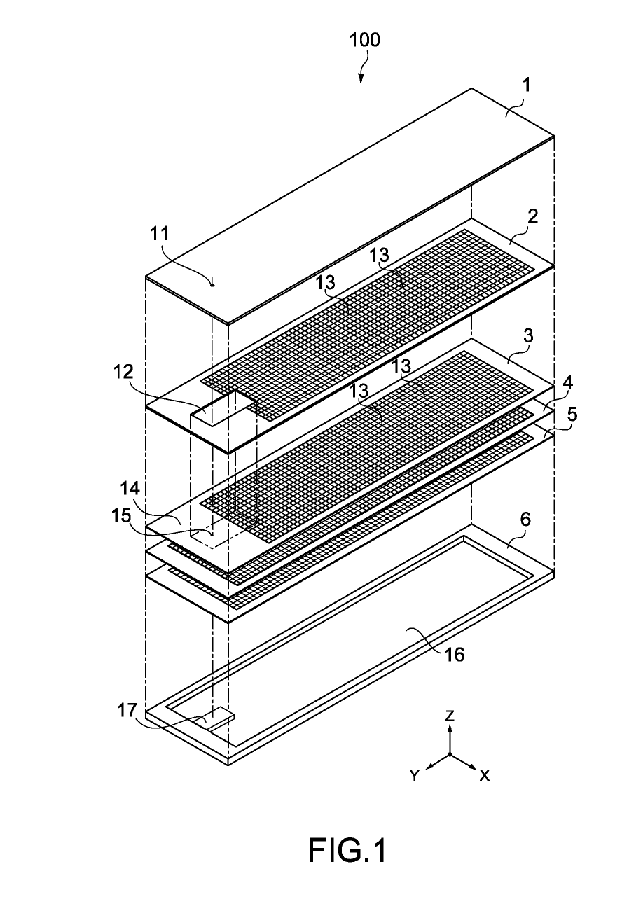

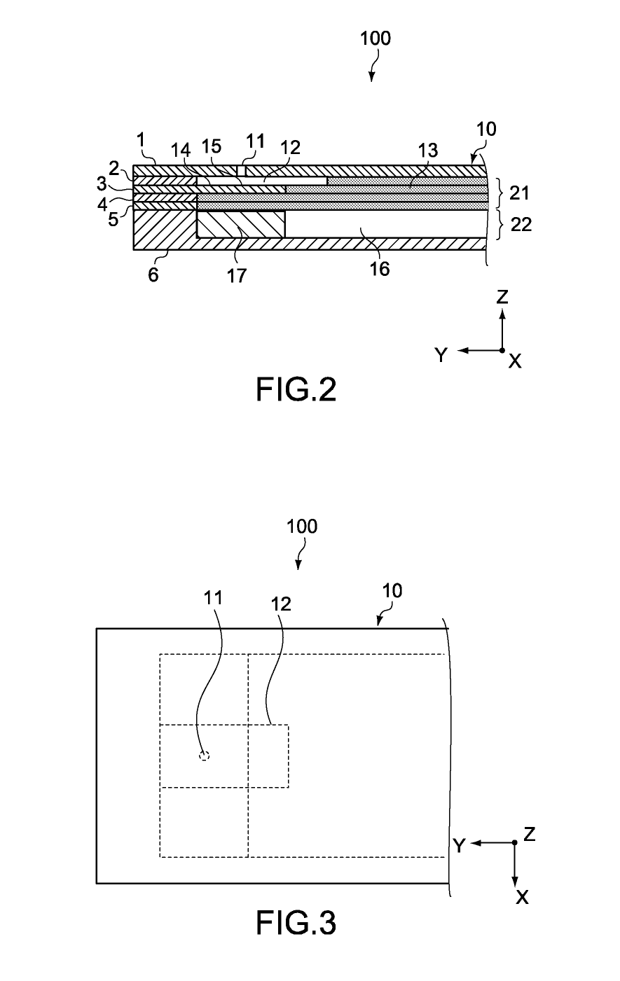

FIG. 1 is an exploded perspective view of a heat-transporting device according to an embodiment of the present invention. FIG. 2 is a cross-sectional diagram of the heat-transporting device. FIG. 3 is a top view of the heat-transporting device. As shown in the figures, a heat-transporting device 100 according to this embodiment is constituted of a plurality of substrates 1 to 6.

The substrates 1 to 6 are each a thin rectangular plate that is elongated in one direction (Y direction), and the substrates all have about the same size. Typically, the substrates 1 to 6 are constituted of oxygen-free copper, tough pitch copper, or a copper alloy.

However, the present invention is not limited thereto, and the substrates 1 to 6 may be constituted of metal other than copper, or a material having high heat conductivity may be used instead. The substrates 1 to 6 are bonded by diffusion bonding (thermal compression bonding), for example. Thus, the heat-transporting device 100 including a casing 10 is formed.

An upper substrate 1 that is disposed at the very top of the substrates and forms an upper portion of the heat-transporting device includes an inlet 11 at an end portion, and a condensable working fluid is injected into the heat-transporting device 100 via the inlet 11. Typically, the condensable working fluid is water or ethanol. A thickness of the upper substrate 1 is typically 0.1 to 0.5 mm, though not limited to this range.

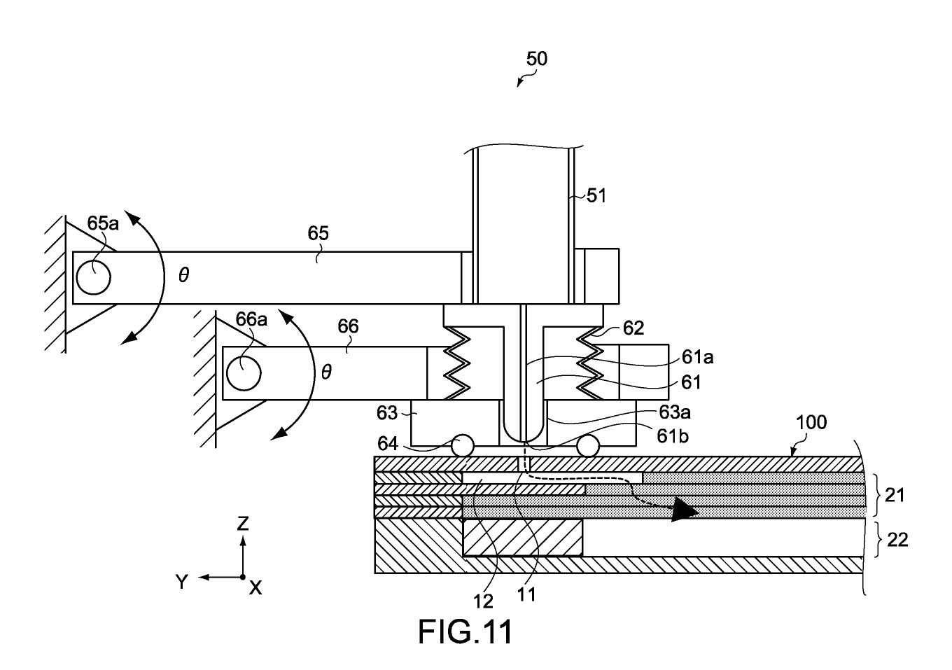

Provided below the upper substrate 1 is an opening substrate 2 that includes an opening 12 and a plurality of holes 13 that constitute a liquid-phase flow path 21 (see FIG. 2). The opening 12 is formed at an end portion of the opening substrate 2 and is rectangular, for example. The opening 12 is formed on the opening substrate 2 such that, when the substrates are bonded, the opening 12 is positioned below the inlet 11 (see FIGS. 2 and 3). By the opening, a predetermined space for pressing the inlet 11 is formed. The plurality of holes 13 may be holes 13 formed by a punch or the like, or may be holes 13 in a mesh structure constituted of a thin metallic wire. In the case of the reticulate mesh structure constituted of a thin metallic wire, intervals of the thin metallic wire in the Y direction can be differentiated from those of the thin metallic wire in an X direction. By setting the intervals of the thin metallic wire in the Y direction to be longer than those of the thin metallic wire in the X direction, a capillary force in the Y direction can be enhanced and cooling performance can be improved. The same holds true for the plurality of holes 13 formed on a solid-core substrate 3 to be described later. The opening 12 and the plurality of holes 13 are formed on the opening substrate 2 such that the opening 12 and the plurality of holes 13 are partially in contact with each other. Accordingly, since the space and the liquid-phase flow path 21 are in communication with each other, the working fluid that has entered the opening 12 via the inlet can be led inside the casing 10 (see FIG. 11).

A thickness of the opening substrate 2 is typically 0.02 mm to 0.05 mm. Similarly, the solid-core substrate 3 and liquid-phase flow path substrates 4 and 5 to be described later each have a thickness of 0.02 mm to 0.05 mm. However, the present invention is not limited thereto, and the thickness may be 0.02 mm or less or 0.05 mm or more.

Provided below the opening substrate 2 is the solid-core substrate 3 that includes the plurality of holes 13 that constitute the liquid-phase flow path 21 and a solid-core portion 14 constituted of a solid core. The solid-core portion 14 is provided at an end portion of the solid-core substrate 3 such that, when the substrates are bonded, the solid-core portion 14 is positioned below the inlet 11 and the opening 12 (see FIG. 2). It should be noted that the solid-core portion 14 partially functions as a contact portion 15 that comes into contact with the inlet 11 when the inlet 11 is pressed to be sealed. Details on the sealing of the inlet 11 will be given later. Further, the plurality of holes 13 are formed on the solid-core substrate 3 such that a part of the plurality of holes 13 formed on the solid-core substrate 3 is in communication with the predetermined space formed by the opening 12. Accordingly, since the space and the liquid-phase flow path 21 are in communication with each other, the working fluid that has entered the opening 12 via the inlet can be led inside the casing 10 smoothly (see FIG. 11).

Provided below the solid-core substrate 3 are the liquid-phase flow path substrates 4 and 5 that each include the plurality of holes 13. By the plurality of holes 13 formed on the opening substrate 2, the solid-core substrate 3, and the liquid-phase flow path substrates 4 and 5, the liquid-phase flow path 21 through which the working fluid of a liquid phase (hereinafter, referred to as liquid-phase working fluid) flows by the capillary force is formed (see FIG. 2).

Provided below the liquid-phase flow path substrate 5 is a lower substrate 6 that forms a lower portion of the heat-transporting device 100. The lower substrate 6 includes a groove 16 that forms a gas-phase flow path 22 through which the working liquid of a gas phase (hereinafter, referred to as gas-phase working fluid) flows (see FIG. 2).

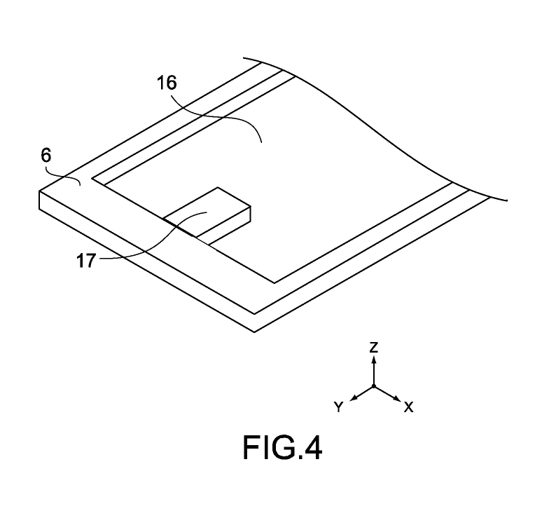

FIG. 4 is an enlarged diagram showing the vicinity of an end portion of the lower substrate 6. As shown in FIG. 4, a convex portion 17 is formed at an end portion of the groove 16. The convex portion 17 is provided inside the groove 16 such that, when the substrates are bonded, the convex portion 17 is positioned below the inlet 11. The convex portion 17 is capable of supporting the contact portion when the inlet 11 is pressed to be sealed.

A thickness of the lower substrate 6 is typically 0.2 mm to 0.8 mm. However, the present invention is not limited thereto, and the thickness may be 0.2 mm or less or 0.8 mm or more.

### Second Embodiment of Heat-Transporting Device

Next, another embodiment of the heat-transporting device will be described. In descriptions below, structures and functions that are the same as those of the above embodiment are denoted by the same reference numerals, and descriptions thereof will be omitted or simplified.

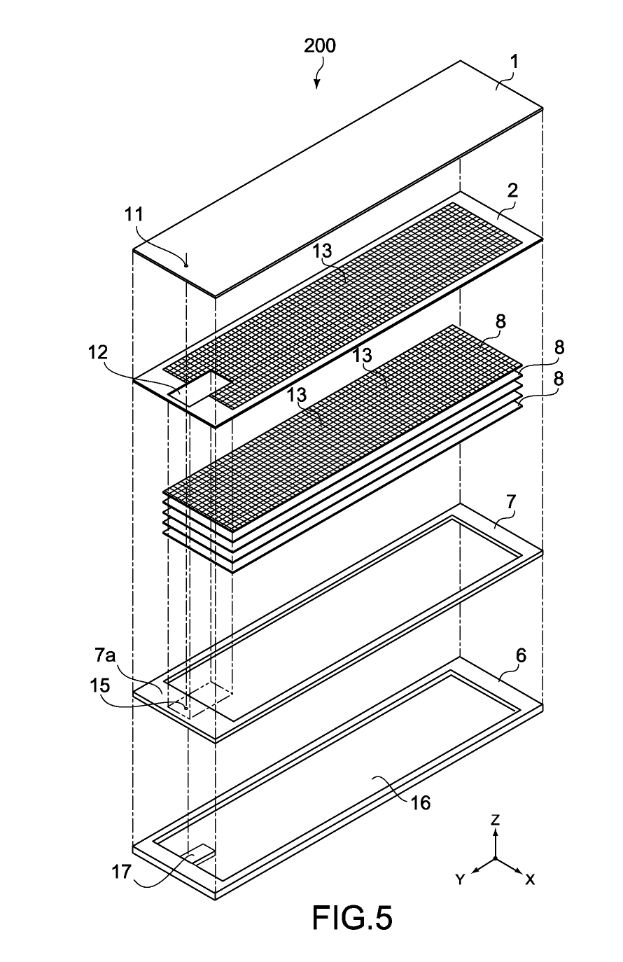

FIG. 5 is an exploded perspective view showing a heat-transporting device 200 according to this embodiment.

As shown in FIG. 5, the heat-transporting device 200 of this embodiment includes the upper substrate 1 including the inlet 11 and the opening substrate 2 including the opening 12. Moreover, the heat-transporting device 200 includes a frame substrate 7 having a frame structure, a plurality of liquid-phase flow path substrates 8 that each include the plurality of holes 13 that constitute the liquid-phase flow path, and the lower substrate 6 including the groove 16 that constitutes the gas-phase flow path.

The frame substrate 7 is disposed at a position interposed between the opening substrate 2 and the lower substrate 6 and includes four edge portions that constitute a frame. An edge portion 7a constituting a short side of the frame substrate 7 is disposed so as to be positioned below the inlet 11 and the opening 12 when the substrates are bonded. The edge portion 7a partially functions as the contact portion 15 that comes into contact with the inlet 11 when the inlet 11 is pressed. A thickness of the frame substrate 7 is typically 0.10 mm to 0.25 mm. However, the present invention is not limited thereto, and the thickness may be 0.10 mm or less or 0.25 mm or more.

On each of the plurality of liquid-phase flow path substrates 8, the plurality of holes 13 for generating the capillary force are formed over an entire surface. The plurality of liquid-phase flow path substrates 8 each having a size that can be accommodated in the frame of the frame substrate 7 are laminated and accommodated in the frame. The number of the plurality of liquid-phase flow path substrates 8 is typically 4 to 6, though not limited thereto. A thickness of each of the plurality of liquid-phase flow path substrates 8 is 0.02 mm to 0.05 mm.

However, the present invention is not limited thereto, and the thickness may be 0.02 mm or less or 0.05 mm or more. Here, the liquid-phase flow path substrates 8 are provided in the frame such that a part of the plurality of holes 13 formed over the entire surface of each of the liquid-phase flow path substrates 8 is in communication with the predetermined space formed by the opening 12. Accordingly, since the space and the liquid-phase flow path 21 are in communication with each other, the working fluid that has entered the opening 12 via the inlet 11 can be led inside the casing 10 smoothly.

### Third Embodiment of Heat-Transporting Device

Next, another embodiment of the heat-transporting device will be described. In this embodiment, a shape of an opening is different from the opening 12 provided on the opening substrate 2 in the heat-transporting device 100 according to the first embodiment above. Thus, this point will mainly be described.

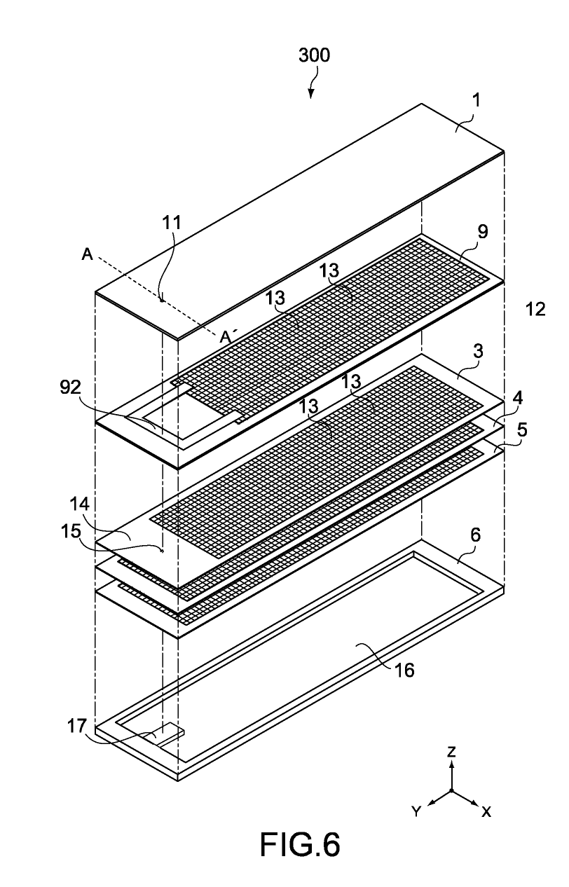

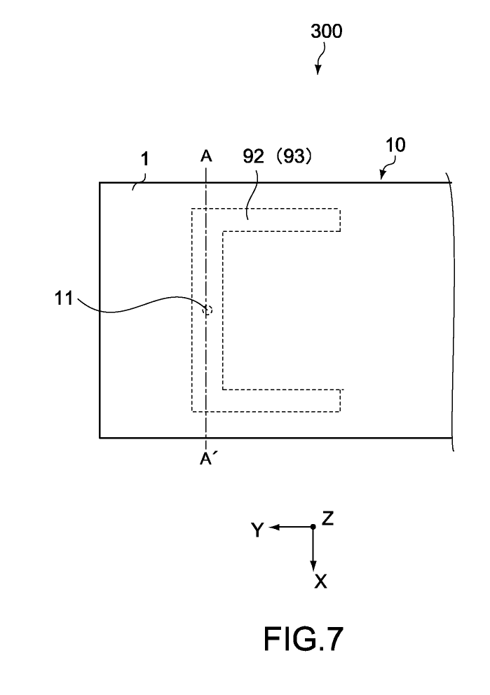

FIG. 6 is an exploded perspective view of a heat-transporting device 300 according to this embodiment. FIG. 7 is a top view of the heat-transporting device 300.

As shown in FIG. 6, the heat-transporting device 300 of this embodiment includes an opening substrate 9 that includes an opening 92 and the plurality of holes 13 constituting the liquid-phase flow path 21. The opening 92 is provided at one end portion of the opening substrate 9 and has a U shape. End portions of the opening 92 are each formed so as to come into contact with a part of the plurality of holes 13 (liquid-phase flow path 21). In addition, the opening 92 is formed on the opening substrate 9 so as to be positioned below the inlet 11 when the substrates are bonded. In this embodiment, by the opening 92, an injecting path 93 for guiding the liquid-phase working fluid injected from the inlet 11 inside the casing 10 is formed (see FIG. 7). The plurality of holes 13 may be formed on the solid-core substrate 3 such that a part of the plurality of holes 13 formed on the solid-core substrate 3 is in communication with the injecting path 93 formed by the opening 92.

Other substrates are the same as those of the first embodiment above, so descriptions thereof will be omitted.

It should be noted that the frame substrate 7 and the liquid-phase flow path substrates 8 laminated inside the frame as shown in FIG. 5 may be disposed below the opening substrate 9.

### Modified Example of Heat-Transporting Device

In the above embodiments, the inlet 11 has been described as being disposed at the end portion of the upper substrate 1. However, the present invention is not limited thereto, and the inlet 11 may be disposed near the center of the upper substrate 1 or at other positions.

In this case, positions of the opening 12 (or opening 92), the contact portion 15, and the convex portion 17 are changed as appropriate in accordance with the position of the inlet 11. For example, in a case where the inlet 11 is formed at the center of the upper substrate 1, the opening 12, the contact portion 15, and the convex portion 17 are provided at centers of the opening substrate 2, the solid-core substrate 3, and the lower substrate 6, respectively.

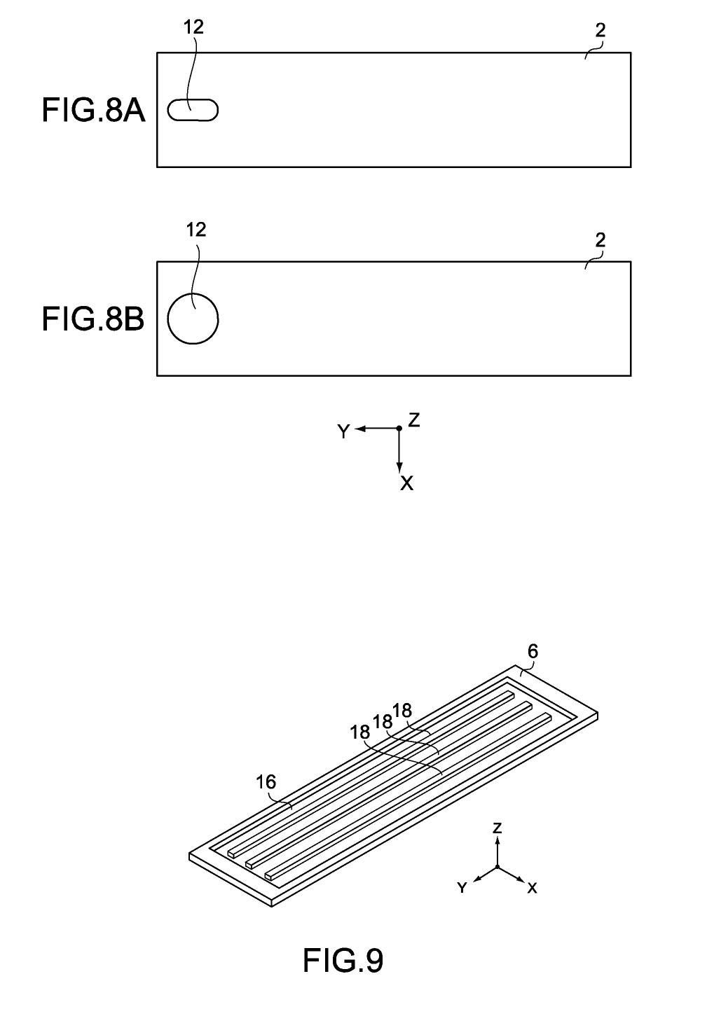

Although the opening 12 provided on the opening substrate 2 has been described as being rectangular, other shapes are also possible. FIG. 8 are diagrams showing examples of a case where the opening has a shape other than a rectangle. FIG. 8A is a diagram showing a case where the opening 12 is oval and FIG. 8B is a diagram showing a case where the opening 12 is circular. In addition, the opening substrate 2 (or opening substrate 9) has been described as being provided with the plurality of holes 13. However, it is possible to generate a sufficient capillary force as the heat-transporting device even without the provision of the plurality of holes 13 on the opening substrate 2 (or opening substrate 9). Here, in a case where the plurality of holes 13 are not provided on the opening substrate 2 (or opening substrate 9), in order to lead the working fluid that has entered the space formed by the opening 12 inside the casing 10, the plurality of holes 13 formed on the solid-core substrate 3 are required to be formed such that a part thereof is in communication with the space. In the case of FIG. 5, a part of the plurality of holes 13 on each of the liquid-phase flow path substrates 8 is required to be in communication with the space.

In addition to or in place of the convex portion 17, columns 18 may be provided inside the groove 16 of the lower substrate 6. FIG. 9 is a perspective view of the lower substrate 6 that includes the columns 18 inside the groove 16. As shown in FIG. 9, the columns 18 are provided inside the groove 16 along a longitudinal direction of the lower substrate 6, that is, along the gas-phase flow path 22. The columns 18 each have a function as a supporting column (beam) for preventing a deformation of the heat-transporting device 100 when the heat-transporting device 100 is heated. For example, when a heat temperature of a heat source such as a CPU is high, an inner pressure of the heat-transporting device 100 (gas-phase flow path 22) rises to thus cause a deformation of the heat-transporting device 100. By providing the columns 18, the deformation of the heat-transporting device 100 due to the rise of the inner pressure of the heat-transporting device 100 can be suppressed. In addition, the columns 18 are capable of supporting the contact portion when the inlet 11 is pressed to be sealed.

### First Embodiment of Sealing Apparatus

Next, a sealing apparatus according to an embodiment of the present invention will be described. It should be noted that in descriptions below, unless stated otherwise, the heat-transporting device will be described as being the heat-transporting device 100 according to the first embodiment above.

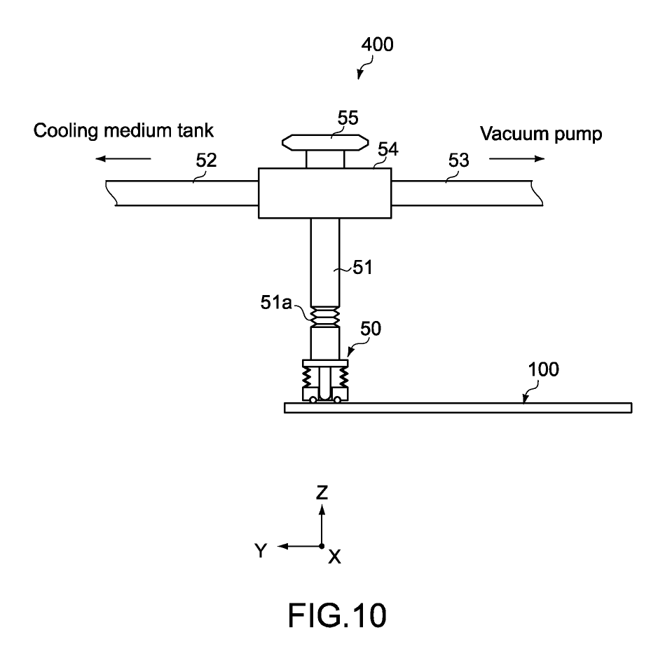

FIG. 10 is an overall view of the sealing apparatus for injecting the working fluid into the heat-transporting device.

As shown in FIG. 10, a sealing apparatus 400 includes a discharging mechanism 50 for discharging the working fluid into the heat-transporting device 100, a pipe 51 connected to the discharging mechanism 50, a cooling medium pipe 52 connected to a cooling medium tank for storing the working fluid, and a vacuum pipe 53 connected to a vacuum pump. In addition, the sealing apparatus 400 includes a valve 54 for switching the connection of the pipe 51 and the cooling medium pipe 52 to the connection of the pipe 51 and the vacuum pipe 53 and vice versa. The valve 54 is provided with a handle 55 for switching the connections.

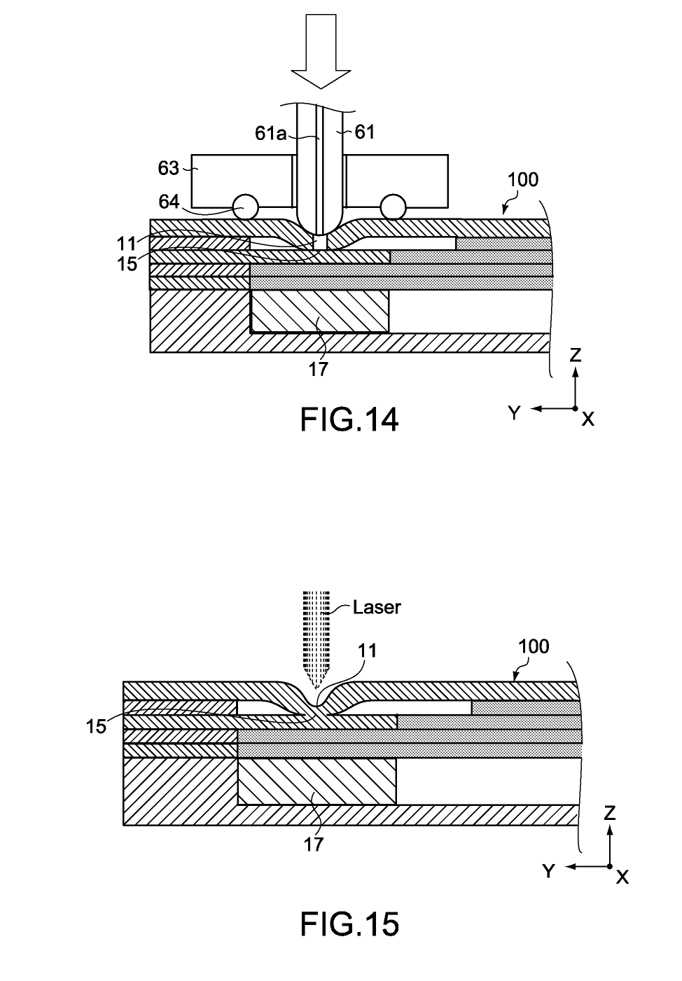

The pipe 51, the cooling medium pipe 52, and the vacuum pipe 53 are made of metal, and a part of the pipe 51 is constituted of a flexible pipe 51a. The flexible pipe 51a may be made of any metal as long as it has flexibility, and may also be made of a resin. Alternatively, the pipe 51 may entirely be flexible. As a result, the pipe 51 can cope with a vertical movement of a discharging member 61 (see FIG. 14).

FIG. 11 is a diagram showing the discharging mechanism of the sealing apparatus.

As shown in FIG. 11, the discharging mechanism 50 includes the discharging member 61 that includes an outlet 61b for discharging the working fluid, a bellows 62 provided so as to surround the discharging member 61, and a base 63 that includes a through-hole 63a through which the discharging member 61 is capable of moving. The discharging mechanism 50 also includes a first driving member 65 for vertically driving the discharging member 61 and a second driving member 66 for driving the base 63.

The discharging member 61 is cylindrical and has an outer diameter of an upper portion larger than an outer diameter of a lower portion. The discharging member 61 is provided with a communicating hole 61a that penetrates from the upper portion to the lower portion (tip end portion). The communicating hole 61a at the tip end portion of the discharging member 61 forms the outlet 61b.

The tip end portion of the discharging member 61 is semispherical and a diameter thereof is typically 3 mm to 5 mm. However, the present invention is not limited thereto, and the diameter of the tip end portion may be 3 mm or less or 5 mm or more as long as the diameter is equal to or larger than the diameter of the inlet 11. The upper portion of the discharging member 61 is coupled to the pipe 51 so as to be capable of injecting the working fluid into the heat-transporting device 100 via the communicating hole 61a and the outlet 61b and exhausting the inside of the heat-transporting device 100 via the outlet 61b and the communicating hole 61a.

The bellows 62 is provided around the discharging member 61. The bellows 62 is connected to the upper portion of the discharging member 61 and can be expanded/contracted according to the drive of the discharging member 61 in the vertical direction.

Provided below the bellows 62 is the base 63 coupled to the bellows 62. The base 63 includes the through-hole 63a penetrating from the upper portion to the lower portion. The discharging member 61 is capable of moving vertically within the through-hole 63a.

An O-ring 64 is provided at the lower portion of the base 63. The O-ring 64 is brought into contact with the heat-transporting device 100 to thus seal a space formed between the discharging member 61 and the heat-transporting device 100.

By the bellows 62, the base 63, and the O-ring 64, airtightness of the space formed between the discharging member 61 and the heat-transporting device 100 can be maintained.

The first driving member 65 has one end portion coupled to an axis 65a and the other end portion coupled to the upper portion of the discharging member 61. The first driving member 65 is rotatable in a θ direction about the axis 65a, and drives the discharging member 61 vertically.

The second driving member 66 has one end portion coupled to an axis 66a and the other end portion coupled to the upper portion of the base 63. The second driving member 66 is rotatable in the θ direction about the axis 66a, and biases the base 63 and the O-ring 64 toward the heat-transporting device 100.

The first driving member 65 and the second driving member 66 are driven using, for example, a screw force, an air pressure, and an electromagnetic force, and a force with which the discharging member 61 is driven or a force with which the base 63 and the O-ring 64 are biased is thus adjusted.

### Modified Example of Sealing Apparatus

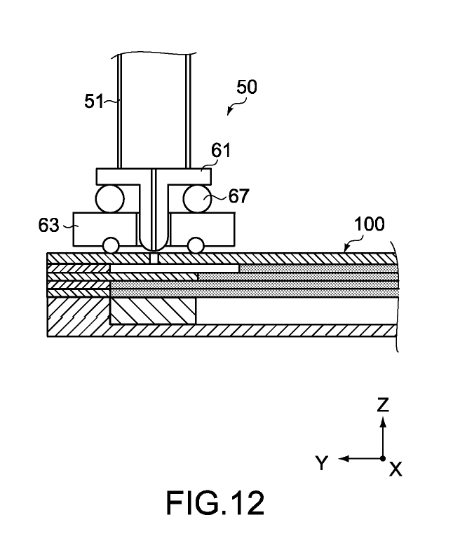

The above descriptions have been given assuming that a member that expands/contracts in accordance with the drive of the discharging member in the vertical direction is the bellows 62. However, the present invention is not limited thereto, and any other member may be used as long as it can expand/contract in accordance with the drive of the discharging member 61 in the vertical direction. FIG. 12 is a diagram showing the discharging mechanism 50 in a case where an O-ring 67 is used instead of the bellows 62.

In this case, the O-ring 67 elastically deforms in accordance with the drive of the discharging member 61 in the vertical direction.

Moreover, the driving direction of the first driving member 65 and the second driving member 66 is not limited to the θ direction. For example, the driving direction of the first driving member 65 and the second driving member 66 may be the vertical direction.

### First Embodiment of Sealing Method of Working Fluid and Method of Producing Heat-Transporting Device

Next, an embodiment regarding a sealing method for sealing the working fluid in the heat-transporting device using the sealing apparatus and a method of producing a heat-transporting device in which the working fluid is sealed will be described.

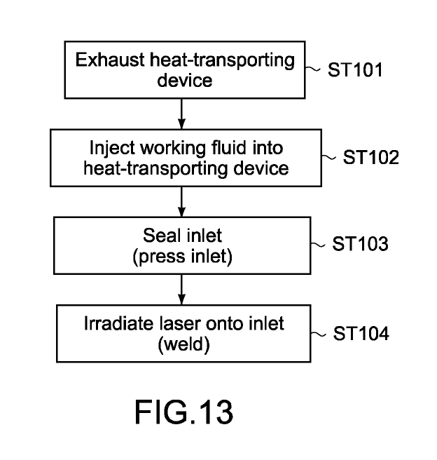

FIG. 13 is a flowchart showing the sealing method and the producing method.

First, using the sealing apparatus 400, the inside of the casing 10 of the heat-transporting device 100 is exhausted (Step 101) and the working fluid is injected into the casing 10 of the heat-transporting device 100 (Step 102). After the working fluid is injected into the heat-transporting device 100, the inlet 11 of the heat-transporting device 100 is pressed and brought into contact with the contact portion 15 so as to be sealed (Step 103). After that, laser is irradiated onto the sealed inlet 11 to thus weld the inlet 11 and the contact portion 15 (Step 104).

Referring to FIGS. 10 and 11, each operation will be described.

First, positioning is performed so that the inlet 11 provided on the upper substrate 1 of the heat-transporting device 100 and the communicating hole 61a (outlet 61b) of the discharging member 61 of the discharging mechanism 50 are positioned on a straight line. A distance between the tip end portion of the discharging member 61 and the inlet 11 of the heat-transporting device 100 is adjusted by the first driving member 65 so that a predetermined distance is provided therebetween.

After the positioning, the base 63 and the O-ring 64 are pressed downward by the second driving member 66 to be biased toward the heat-transporting device 100. Accordingly, the space between the discharging member 61 and the inlet 11 is kept airtight.

Next, after the handle 55 is operated and the pipe 51 and the vacuum pipe 53 are thus connected, the inside of the heat-transporting device 100 is exhausted by the vacuum pump via the inlet 11, the outlet 61b, and the communicating hole 61a (Step 101).

When the inside of the heat-transporting device 100 is exhausted, the pipe 51 and the cooling medium pipe 52 are connected by the operation to the handle 55. Then, a working fluid such as water or ethanol is injected into the heat-transporting device 100 from the cooling medium tank via the communicating hole 61a, the outlet 61b, and the inlet 11 (Step 102). The working fluid that has been injected into the heat-transporting device 100 enters the space formed by the opening 12 and is led to the liquid-phase flow path 21. An amount of working fluid to be injected into the heat-transporting device 100 is adjusted as appropriate. Here, because the tip end portion of the discharging member 61 is positioned a predetermined distance apart from the inlet 11 as described above, the working fluid can be led inside the heat-transporting device 100 smoothly.

After the working fluid is injected into the heat-transporting device 100, the discharging member 61 is driven downwardly by the first driving member 65.

FIG. 14 is a diagram showing a state where the discharging member 61 is driven downwardly. As shown in FIG. 14, when the discharging member 61 is driven downwardly, the inlet 11 is pressed by the tip end portion of the discharging member 61 to thus be brought into contact with the contact portion 15, thus sealing the inlet 11 (Step 103). In this case, the convex portion 17 supports the contact portion 15. A force of the tip end portion of the discharging member 61 pressing the inlet 11 is typically 400 N to 500 N (≈40 kgf to 50 kgf). However, the present invention is not limited thereto, and the force may be 400 N or less or 500 N or more. It should be noted that when the discharging member 61 is driven downwardly, the bellows 62 contracts accordingly. In other words, due to the bellows 62, even when the discharging member 61 moves, a predetermined space formed between the discharging member 61 and the heat-transporting device 100 can be maintained airtight.

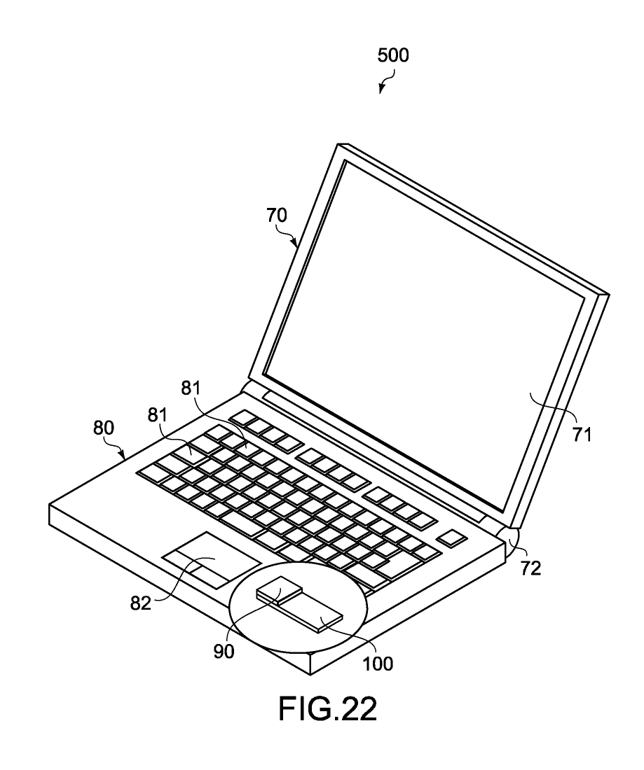

As shown in FIG. 14, by pressing the inlet 11 and bringing the inlet into contact with the contact portion 15 to thus seal the inlet 11, the working fluid can positively be sealed in the heat-transporting device 100. In addition, because the inlet 11 is sealed by being pressed, no protrusion is caused, with the result that it becomes possible to attach the heat-transporting device 100 even in a small space inside an electronic apparatus, for example (see FIG. 22). Furthermore, because a thermoplastic metal such as solder is not used in sealing the inlet 11, a situation where the thermoplastic metal melts due to heat in a reflow process and the like does not occur, with the result that reliability on internal airtightness of the heat-transporting device 100 can be improved.

Upon sealing the inlet 11, the discharging mechanism 50 is moved upward by the first driving member 65 and the second driving member 66 and detached from the heat-transporting device 100. Next, laser is irradiated onto the inlet 11 of the heat-transporting device 100 (Step 104).

FIG. 15 is a diagram showing a state where the pressed inlet 11 is irradiated with laser. YAG (Yttrium Aluminum Garnet) laser is typically used for the laser, but carbon dioxide laser or other laser may also by used. The inlet 11 and the contact portion 15 are welded by the irradiation of the YAG laser. Accordingly, the working fluid can more positively be sealed in the heat-transporting device 100, and reliability on internal airtightness of the heat-transporting device 100 can be improved.

Moreover, as described above, the sealing apparatus 400 has the function of exhausting the inside of the heat-transporting device 100 (casing 10), the function of injecting the working fluid into the heat-transporting device 100, and the function of sealing the inlet 11 by pressing the inlet 11. Accordingly, it is possible to efficiently seal the working fluid in the heat-transporting device 100 (produce a heat-transporting device in which a working fluid is sealed) using the sealing apparatus 400.

### Second Embodiment of Sealing Method of Working Fluid and Method of Producing Heat-Transporting Device

Next, another embodiment regarding the sealing method for sealing the working fluid in the heat-transporting device and the method of producing a heat-transporting device in which the working fluid is sealed will be described.

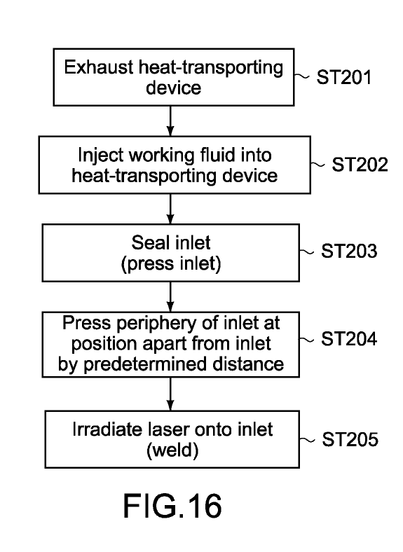

FIG. 16 is a flowchart showing the sealing method and the producing method. The flowchart of FIG. 16 is different from that of FIG. 13 in that, after the inlet 11 is pressed and sealed (Step 203) but before irradiating the laser onto the inlet 11 (Step 205), the periphery of the inlet 11 is pressed at a position a predetermined distance apart from the inlet 11 (Step 204).

Therefore, this point will mainly be described.

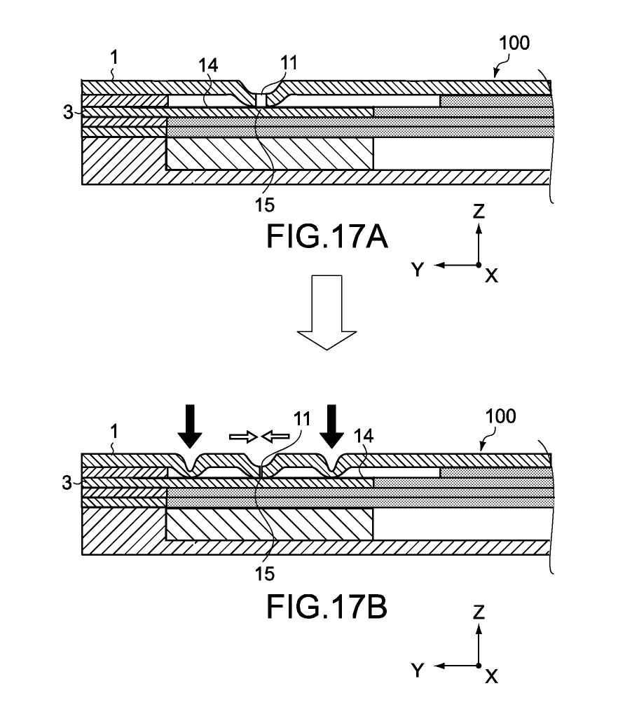

FIG. 17A is a diagram showing a state where the inlet 11 is pressed by the tip end portion of the discharging member 61 and is thus sealed, and FIG. 17B is a diagram showing a state where two points on the periphery of the inlet 11 are pressed.

As shown in FIG. 17B, the two points a predetermined distance apart from the inlet 11 are pressed to be brought into contact with the solid-core portion 14 of the solid-core substrate 3, for example. Then, by the pressing at the two points, a hole width of the inlet 11 is narrowed. Accordingly, when laser is irradiated and the inlet 11 and the contact portion 15 are welded (Step 205, see FIG. 15), the inlet 11 can be sealed more positively. It should be noted that when the two points are pressed and brought into contact with the solid-core portion 14, the convex portion 17 supports the solid-core portion 14.

The number of points that are pressed on the periphery of the inlet 11 is not limited to two, and three or more points may be pressed, for example. Alternatively, the periphery of the inlet may be pressed circularly while keeping a predetermined distance from the inlet.

### Third Embodiment of Sealing Method of Working Fluid and Method of Producing Heat-Transporting Device

Next, another embodiment regarding the sealing method for sealing the working fluid in the heat-transporting device and the method of producing a heat-transporting device in which the working fluid is sealed will be described.

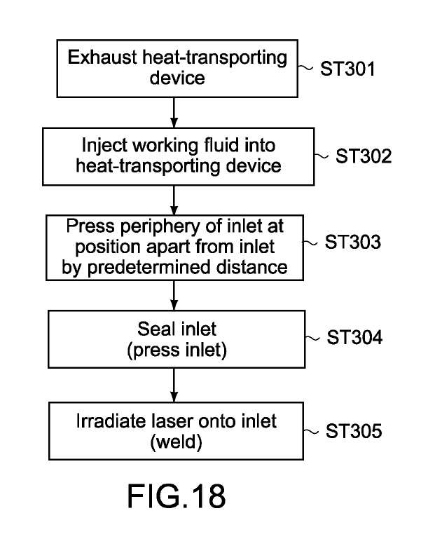

FIG. 18 is a flowchart showing the sealing method and the producing method. In the flowchart, after the working fluid is injected into the heat-transporting device (Step 302) but before pressing the inlet 11 of the heat-transporting device to thus seal the inlet 11 (Step 304), the periphery of the inlet 11 is pressed at a position a predetermined distance apart from the inlet 11 (Step 303). Therefore, this point will mainly be described. It should be noted that in this embodiment, descriptions will be given assuming that an injection target into which the working fluid is to be injected is the heat-transporting device 300 according to the third embodiment above.

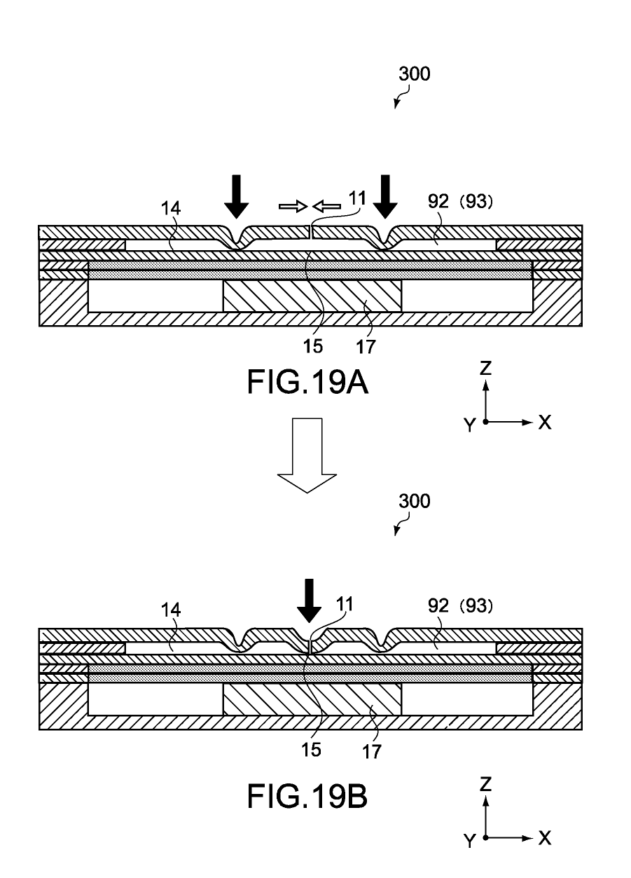

FIG. 19 are cross-sectional diagrams of the heat-transporting device 300 shown in FIGS. 6 and 7 taken along the line A-A′. FIG. 19A is a diagram showing a state where two points a predetermined distance apart from the inlet 11 are pressed, and FIG. 19B is a diagram showing a state where the inlet 11 is pressed.

After the working fluid is injected into the heat-transporting device 300 (Step 302), two points a predetermined distance apart from the inlet 11 on the periphery of the inlet 11 are pressed as shown in FIG. 19A (Step 303). The two points that are pressed are two points on the U-shaped opening 92, that is, two points on the injecting path 93 that leads the working fluid inside the casing 10 (see FIG. 7). In this case, the two points are pressed so as to be brought into contact with the solid-core portion 14 of the solid-core substrate 3, and the convex portion 17 supports the solid-core portion 14.

By the pressing at the two points, the hole width of the inlet 11 can be made narrow and the injecting path 93 can be blocked at the two points.

After the two points are pressed and the injecting path 93 is blocked, the inlet 11 is sealed by being pressed by the tip end portion of the discharging member 61 as shown in FIG. 19B (Step 304). After that, the inlet 11 and the contact portion 15 are welded by the YAG laser, for example (Step 305). Since the hole width of the inlet 11 is narrowed when irradiating the laser, the inlet 11 can be sealed more positively.

Moreover, in this embodiment, particularly because the inlet 11 is sealed after the injecting path 93 is blocked at the two points, the working fluid can be sealed in the heat-transporting device 300 at a total of three points including the two points and the inlet 11. Accordingly, reliability on internal airtightness of the heat-transporting device 300 can be additionally improved.

### Modified Example of Sealing Method of Working Fluid and Method of Producing Heat-Transporting Device

In the above embodiment on the sealing apparatus and the embodiments on the sealing method and the method of producing a heat-transporting device, the injection target into which the working fluid is injected has been described as being the heat-transporting device 100 or the heat-transporting device 300. However, the present invention is not limited thereto, and the injection target may be any of the heat-transporting device 100, the heat-transporting device 200, and the heat-transporting device 300. The injection target is not limited to the heat-transporting devices 100, 200, and 300. For example, as long as the heat-transporting device is provided with the inlet 11 on the casing 10 and the contact portion 15 that comes into contact with the inlet 11 is provided inside the casing 10, it is possible to efficiently seal the working fluid in the heat-transporting device (produce a heat-transporting device in which the working fluid is sealed) using the sealing apparatus 400.

(Operation of Heat-Transporting Device)

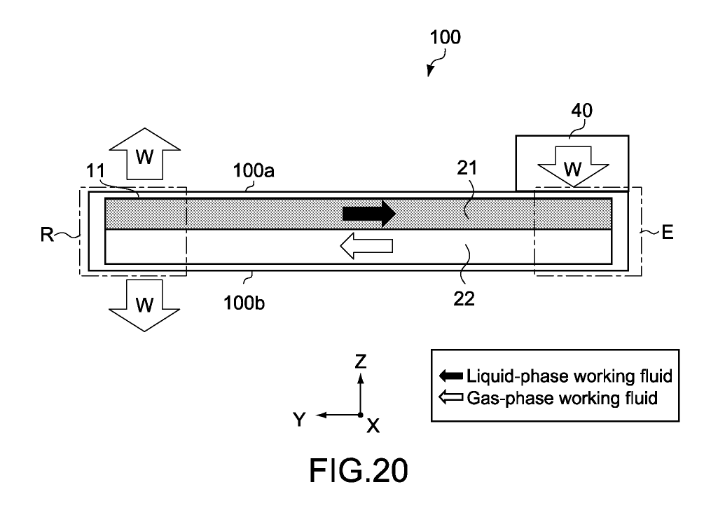

Next, an operation of the heat-transporting device structured as described above will be described. FIG. 20 is a diagram schematically showing a movement of heat in the heat-transporting device.

As shown in FIG. 20, the heat-transporting device 100 has one end portion on an upper surface 100a in contact with a heat source 40 such as a CPU and includes an endothermic portion E at the end portion that is in contact with the heat source and a heat dissipating portion R at the other end portion. The liquid-phase working fluid absorbs heat W from the heat source 40 such as a CPU at the endothermic portion E, changes its phase from the liquid-phase working fluid to the gas-phase working fluid, and moves from the liquid-phase flow path 21 to the gas-phase flow path 22. The gas-phase working fluid moves in a direction from the endothermic portion E to the heat dissipating portion R in the gas-phase flow path 22 and dissipates the heat W at the heat dissipating portion R. Upon dissipating the heat W at the heat dissipating portion R, the gas-phase working fluid changes its phase from the gas-phase working fluid to the liquid-phase working fluid and moves toward the endothermic portion E from the heat dissipating portion R by the capillary force of the plurality of holes 13. The liquid-phase working fluid that has reached the endothermic portion E by the capillary force again absorbs heat W from the heat source 40 such as a CPU and moves from the liquid-phase flow path 21 to the gas-phase flow path 22. By such a phase change of the working fluid, the heat-transporting device 100 can cool the heat W of the heat source 40 such as a CPU. The heat dissipating portion R may be provided with, for example, a heat sink or a fan.

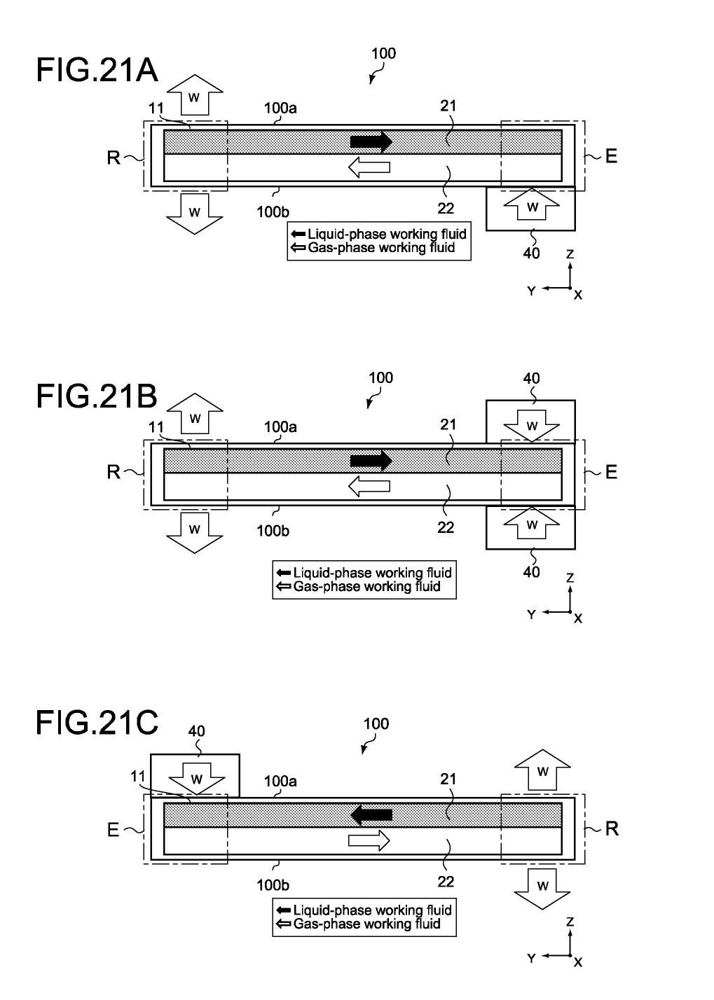

In the description made with reference to FIG. 20, the position that comes into contact with the heat source 40 such as a CPU has been the one end portion of the upper surface 100a. However, the position that comes into contact with the heat source 40 may be on a lower surface 100b of the heat-transporting device. FIG. 21A is a diagram showing a movement of the heat W in a case where the heat source 40 is in contact with the lower surface 100b of the heat-transporting device. Alternatively, the heat source 40 may be in contact with both the upper surface 100a and the lower surface 100b of the heat-transporting device 100. FIG. 21B is a diagram showing a movement of the heat W in a case where the heat sources are in contact with both the surfaces.

Alternatively, the end portion on the other side of the end portion that has been in contact with the heat source in FIG. 20 (end portion on inlet 11 side) may be in contact with the heat source 40. FIG. 21C is a diagram showing a movement of heat in a case where the heat source 40 is in contact with the end portion on the inlet 11 side. Positions of the endothermic portion E and the heat dissipating portion R and the direction in which the working fluid flows in FIG. 21C are opposite to those in FIGS. 20, 21A, and 21B. In other words, the positions of the endothermic portion E and the heat dissipating portion R and the direction in which the working fluid flows are determined relative to the position at which the heat source 40 comes into contact with the heat-transporting device 100. The heat source 40 may be in contact with the end portion of the lower surface 100b on the inlet 11 side or both the upper and lower surfaces 100a and 100b.

(Electronic Apparatus)

Next, an electronic apparatus including a heat-transporting device will be described. In this embodiment, a laptop PC is exemplified as the electronic apparatus.

FIG. 22 is a perspective view of a laptop PC 500. The PC 500 includes a first casing 70 including a display portion 71 and a second casing 80 including a plurality of input keys 81 and a touchpad 82. The first casing 70 and the second casing 80 are rotatable via a hinge portion 72.

The PC 500 has, inside the second casing 80, a CPU 90 (or MPU (Micro Processing Unit)) and the heat-transporting device 100 that is in contact with the CPU 90.

The electronic apparatus is not limited to the laptop PC and may instead be a desktop PC, a display apparatus constituted of a liquid crystal display, or a cellular phone.

The present application contains subject matter related to that disclosed in Japanese Priority Patent Application JP 2008-180763 filed in the Japan Patent Office on Jul. 10, 2008, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A heat-transporting device, comprising:
a casing including a first side and a second side opposed to the first side;
a working fluid that is sealed inside the casing and transports heat by a phase change;
a first substrate that includes an inlet through which the working fluid is injected and constitutes the first side of the casing;
a second substrate that is disposed opposite to the first substrate and constitutes the second side of the casing; and
a third substrate that includes a contact portion that is brought into contact with the inlet so that the inlet is sealed when the inlet is pressed, the third substrate being interposed between the first substrate and the second substrate.

2. The heat-transporting device according to claim 1, further comprising
a fourth substrate that includes an opening that forms a space for pressing the inlet, the fourth substrate being interposed between the first substrate and the third substrate.

3. The heat-transporting device according to claim 2,
wherein the second substrate includes a groove that constitutes a gas-phase flow path through which the working fluid of a gas phase flows.

4. The heat-transporting device according to claim 3,
wherein the third substrate has a frame structure, the heat-transporting device further comprising a plurality of liquid-phase flow path substrates that each include a plurality of holes that constitute a liquid-phase flow path through which the working fluid of a liquid phase flows by a capillary force, the plurality of liquid-phase flow path substrates being laminated inside the frame such that the liquid-phase flow path constituted of the plurality of holes is in communication with the space.

5. The heat-transporting device according to claim 3,
wherein the third substrate further includes a plurality of holes that constitute a liquid-phase flow path through which the working fluid of a liquid phase flows by a capillary force, the plurality of holes being formed such that the liquid-phase flow path constituted of the plurality of holes is in communication with the space.

6. The heat-transporting device according to claim 3,
wherein the fourth substrate further includes a plurality of holes that constitute a liquid-phase flow path through which the working fluid of a liquid phase flows by a capillary force, the plurality of holes being formed such that the liquid-phase flow path constituted of the plurality of holes is in communication with the space.

7. The heat-transporting device according to claim 3,
wherein the second substrate further includes a supporting portion provided inside the groove to support the contact portion when the inlet is pressed.

8. The heat-transporting device according to claim 3,
wherein the second substrate further includes a column provided inside the groove along a directing in which the working fluid of the gas phase flows.

9. The heat-transporting device according to claim 5, further comprising
a plurality of liquid-phase flow path substrates each including a plurality of holes that constitute a liquid-phase flow path through which the working fluid of a liquid phase flows by a capillary force, the plurality of liquid-phase flow path substrates being laminated while interposed between the second substrate and the third substrate.

10. A heat-transporting device, comprising:
a casing including an inlet;
a working fluid that is injected into the casing via the inlet and transports heat by a phase change; and
a contact portion that is provided inside the casing and brought into contact with the inlet to seal the inlet when the inlet is pressed.

11. An electronic apparatus, comprising:
a heat source; and
a heat-transporting device including a casing including an inlet, a working fluid that is injected into the casing via the inlet and transports heat by a phase change, and a contact portion that is provided inside the casing and brought into contact with the inlet to seal the inlet when the inlet is pressed.

12. A sealing apparatus sealing a working fluid in a heat-transporting device that includes a casing including an inlet through which the working fluid for transporting heat by a phase change is injected, the casing sealing the working fluid therein, and a contact portion that is provided inside the casing and brought into contact with the inlet to seal the inlet when the inlet is pressed, the sealing apparatus comprising:
a discharging member including a tip end portion and an outlet provided at the tip end portion from which the working fluid is discharged, the discharging member discharging the working fluid into the casing from the outlet via the inlet; and
a first driving member to drive the discharging member so that the inlet is pressed by the tip end portion.

13. The sealing apparatus according to claim 12,
wherein the discharging member is capable of exhausting the inside of the casing from the outlet via the inlet.

14. The sealing apparatus according to claim 12, further comprising
an airtight mechanism to maintain a space formed between the discharging member and the inlet airtight.

15. The sealing apparatus according to claim 14,
wherein the airtight mechanism includes
an expanding/contracting member that is disposed around the discharging member and expands/contracts in accordance with the drive of the discharging member,
a base that is bonded to the expanding/contracting member and includes a through-hole through which the driven discharging member is capable of moving, and
a sealing member that is provided to the base and seals the space by being brought into contact with the casing.

16. The sealing apparatus according to claim 15, further comprising
a second driving member to drive the base and the sealing member so that the base and the sealing member are biased toward the casing.

17. A working fluid sealing method, comprising:
injecting a working fluid into a casing via an inlet provided to the casing; and
pressing the inlet and bringing the inlet into contact with a contact portion provided inside the casing to thus seal the inlet.

18. The working fluid sealing method according to claim 17, further comprising
exhausting the inside of the casing via the inlet before the injection of the working fluid.

19. The working fluid sealing method according to claim 17, further comprising
welding the inlet and the contact portion by irradiating laser onto the inlet after the sealing of the inlet.

20. The working fluid sealing method according to claim 19, further comprising
pressing, after the injection of the working fluid but before the welding of the inlet and the contact portion by the laser, a periphery of the inlet at a position apart from the inlet by a predetermined gap.

21. A method of producing a heat-transporting device, comprising:
injecting a working fluid into a casing via an inlet provided to the casing; and
pressing the inlet and bringing the inlet into contact with a contact portion provided inside the casing to thus seal the inlet.

22. The method of producing a heat-transporting device according to claim 21, further comprising
exhausting the inside of the casing via the inlet before the injection of the working fluid.

23. The method of producing a heat-transporting device according to claim 21, further comprising
welding the inlet and the contact portion by irradiating laser onto the inlet after the sealing of the inlet.

24. The method of producing a heat-transporting device according to claim 23, further comprising
pressing, after the injection of the working fluid but before the welding of the inlet and the contact portion by the laser, a periphery of the inlet at a position apart from the inlet by a predetermined gap.
